(19) United States
(12) Patent Application Publication
(10) Pub. No.: US 2011/0303938 A1
(43) Pub. Date: Dec. 15, 2011

(54) Group III nitride semiconductor light-emitting element

(75) Inventors: Toshiya Uemura, Kiyosu-shi (JP); Naoki Arazoe, Kiyosu-shi (JP); Yuhei Ikemoto, Kiyosu-shi (JP)

(73) Assignee: Toyoda Gosei Co., Ltd., Kiyosu-shi (JP)

(21) Appl. No.: 12/926,837

(22) Filed: Dec. 13, 2010

(30) Foreign Application Priority Data
Jun. 15, 2010 (JP) P.2010-136121

(51) Int. Cl. H01L 33/00

(52) U.S. Cl. 257/98; 257/E33.055

(57) ABSTRACT

A group III nitride semiconductor light-emitting element having improved light extraction efficiency is provided. The light-emitting element has a plurality of dot-like grooves formed on a surface at the side joining to a p-electrode of a p-type layer. The groove has a depth reaching an n-type layer. Side surface of the groove is slanted such that a cross-section in an element surface direction is decreased toward the n-type layer from the p-type layer. Fine irregularities are formed on the surface at the side joining to an n-electrode of the n-type layer, except for a region on which the n-electrode is formed, and a translucent insulating film having a refractive index of from 1.5 to 2.3 is formed on the fine irregularities. Light extraction efficiency is improved by reflection of light to the n-type layer side by the groove and prevention of reflection to the n-type layer side by the insulating film.

### BACKGROUND OF THE INVENTION

1. Field of the Invention

The present invention relates to a group III nitride semiconductor light-emitting element from which a growth substrate has been removed by a substrate lift-off process, and which has been bonded to a support.

2. Description of the Related Art

A sapphire substrate is generally used as a growth substrate of a group III nitride semiconductor. However, sapphire has the problems in electro-conductivity and thermal conductivity, does not have a clear cleavage surface, and is not easy to be processed. In view of this, a technique (substrate lift-off process) of removing a growth substrate after growing a group III nitride semiconductor on the growth substrate is developed as the technique of solving those problems.

One technique is a laser lift-off process. This technique is a process of separating and removing a growth substrate, comprising joining a group III nitride semiconductor layer and a supporting substrate and irradiating the interface between the growth substrate and the group III nitride semiconductor with laser to decompose the group III nitride semiconductor layer. Another technique is a process (chemical lift-off process) of removing a growth substrate, comprising introducing a chemical-soluble layer into a layer close to a growth substrate of a group III nitride semiconductor layer, joining the group III nitride semiconductor layer and a supporting substrate, and then dissolving the chemical-soluble layer in the above chemical by a desired chemical.

In such a, group III nitride semiconductor light-emitting element in which the growth substrate has been removed, and which has been joined to the supporting substrate, a technique of improving light extraction efficiency is shown in Patent Document 1. In the light-emitting element described in Patent Document 1, a depressed portion for light reflection, having a depth reaching a n-type layer from a surface at the side joining to a p-electrode, of a p-type layer is provided, and a side surface of the depressed portion is slanted such that a cross-section in an element surface direction is decreased toward an n-type layer from the p-type layer. Light confined in the vicinity of an active layer and propagated in the element surface direction is reflected to the n-type layer side by the depressed portion for reflection, thereby improving light extraction efficiency.
Patent Document 1: JP-A 2008-205005

However, even in the case that a depressed portion for light reflection was provided as in Patent Document 1, a part of light reflected to the n-type layer side by the depressed portion for light reflection reflects on the surface at a side joining to an n-electrode, of the n-type layer, and returns to the inside of the element. As a result, the light extraction efficiency has not sufficiently been improved.

### SUMMARY OF THE INVENTION

Accordingly, an object of the present invention is to provide a group III nitride semiconductor light-emitting element having improved light extraction efficiency, and a method for producing the element.

A first invention is a group III nitride semiconductor light-emitting element comprising a conductive support; a p-electrode located on the support; a p-type layer comprising a group III nitride semiconductor, an active layer and an n-type layer, located on the p-electrode in this order; an n-electrode located on the n-type layer, the n-type layer having fine irregularities provided at a surface of the n-type layer that is located at the n-electrode side, a translucent insulating film having a refractive index of from 1.5 to 2.3, formed so as to cover the fine irregularities, a groove having a depth reaching at least the n-type layer from the surface of the p-type layer that is located at the p-electrode side, and a translucent insulating protective layer formed on the side surface and the bottom surface of the groove; and the side surface of the groove has a slant such that a cross-section in an element surface direction of the groove is decreased toward the n-type layer side.

The group III nitride semiconductor used herein is a semiconductor represented by the general formula AlₓGa_{y}In_{z}N (x+y+z=1 and 0≦x,y,z≦1), and includes the semiconductor wherein a part of Al Ga and In is substituted with B and TI that are other group 13 elements, and the semiconductor wherein a part of N is substituted with P, As, Sb and Bi that are other group 15 elements. More generally, the semiconductor indicates GaN, InGaN, AlGaN, AlGaInN, containing at least Ga. Si is generally used as n-type impurity, and Mg is generally used as p-type impurity.

The insulating film having translucency and a refractive index of from 1.5 to 2.3 can use Al₂O₃, CeO₂, HfO₂, MgO, Nb₂O₅, Ta₂O₅, Y₂O₃, ZrO₂ and the like. The refractive index in the present specification means a refractive index at a light-emitting wavelength of the group III nitride semiconductor element. The more desired refractive index of the insulating film is from 1.7 to 2.1. The translucency in the present specification means translucency to a light-emitting wavelength of the group III nitride semiconductor element.

It is desired that the fine irregularities are not provided in an n-electrode formation region on the surface of the n-type layer, and the n-electrode formation region remains flat. The reason for this is to prevent the phenomenon that light is multiply-reflected between the n-type layer and the irregularities and decays, and the light extraction efficiency is deteriorated.

The groove can have an optional pattern, and has a line-like pattern such as a stripe shape or a lattice shape, and a pattern having a plurality of dots. Single groove or a plurality of groves may be provided in a dot shape, and may be provided in a line shape such as a straight line shape or a curve shape.

The slant of the side surface of the grove is desirably from 30 to 85°, and more desirably from 40 to 80°, to the surface of the element.

The shape in the case that the groove is provided in a dot shape may be any shape such as pyramid, circular cone, truncated pyramid and circular truncated cone, and may be an infinite form. In the case that a plurality of dot-like grooves is provided, it is desired that the grooves are uniformly provided as a periodical arrangement with equal intervals, such as arranging in a matrix shape. The reason for this is that uniformity of light emission can be enhanced. In the case that a shape of the groove has its cross-section in an element surface direction of a circle, a diameter on the p-type layer surface of the groove is desirably from 0.5 to 50 μm, and more desirably from 1 to 5 μm. Furthermore, a diameter of the bottom surface of the groove is desirably from 0 to 45 μm, and more desirably from 0 to 4.5 μm.

In the case that the groove has a pattern comprising a plurality of straight lines, interval and width of the lines are desirably uniform. Furthermore, in the case that the pattern of the groove is a line shape, line width on the p-type layer surface is desirably from 0.5 to 30 μm, and more desirably from 1 to 15 μm. The line width on the bottom surface of the groove is desirably from 0 to 25 μm, and more desirably from 0 to 12 μm.

The protective layer is provided to prevent leakage and short circuit of current. In the case that the protective layer is a dielectric material, the protective layer may be formed on the bottom surface and the side surface of the groove in a film form, and may be formed so as to fill in the whole groove. In the case that a dielectric material which is the protective layer is formed on the side surface and the bottom surface of the groove in a film form, it is desired that a high reflection layer is desirably provided on the side surface and the bottom surface of the groove through the protective layer. The high reflection layer may be formed in a layer form, and may be formed so as to fill in the grove. Furthermore, the p-electrode comprising a high reflection material may be the high reflection layer. In the case that a high reflection layer such as the p-electrode is not provided on the outer side (inner side of the grove) of the protective layer, the dielectric material which is the protective layer is desirably a material having a refractive index smaller than that of the material having the smallest refractive index in the materials constituting the n-type layer, the active layer and the p-type layer. The reason for this is that light propagated in an element surface direction in the vicinity of the active layer is totally reflected to the n-type layer side. Furthermore, the protective layer may be a multilayered film and have the structure of utilizing Bragg reflection. The protective layer may be a high resistant ion-implanted region in a film form by implanting ions in the bottom surface and the side surface of the groove. The ion to be implanted can use Ar, N and the like. Thus, when the protective layer is an ion-implanted region and the p-electrode is formed on the bottom surface and the side surface of the groove through the ion-implanted region, light reflectance to the n-type layer side can be increased without impairing adhesiveness of the p-electrode. Even in the case that the ion-implanted region is used as the protective layer, the p-electrode may be formed so as to fill in the groove, and may be formed in a layer form along the side surface and the bottom surface of the groove.

The n-electrode is desirably formed in a wiring pattern such as a comb teeth shape, a stripe shape or a lattice shape. The reason for this is that the pattern improves current diffusivity in an element surface direction, makes light emission uniform, and inhibits rise in driving voltage.

The growth substrate is generally sapphire, but other than sapphire, SiC, ZnO, spinel and the like can be used. The support can use a substrate of Si, Ge, GaAs, Cu, Cu—W or the like. The p-electrode can be formed on the support by joining the p-electrode and the support through a metal layer. The metal layer can use a metal eutectic layer such as Au—Sn layer, Au—Si layer, Ag—Sn—Cu layer or Sn—Bi layer, and can further use Au layer, Sn layer, Cu layer and the like. A metal layer such as Cu may directly be formed on the p-electrode by plating or sputtering, thereby forming a support.

A second invention is a group III nitride semiconductor light-emitting element, wherein in the first invention, the groove has a dot shape, and a plurality of grooves are formed.

A third invention is a group III nitride semiconductor light-emitting element, wherein in the second invention, the grooves are arranged in a matrix shape.

A fourth invention is a group III nitride semiconductor light-emitting element, wherein in the first invention, the grooves are formed in a lattice shape.

A fifth invention is a group III nitride semiconductor light-emitting element, wherein in the first to fourth inventions, the protective layer is a dielectric material formed so as to fill in the groove.

A sixth invention is a group III nitride semiconductor light-emitting element, wherein in the first to fourth inventions, the protective layer is a dielectric material formed in a film form, and the groove is filled with the p-electrode through the protective layer.

A seventh invention is a group III nitride semiconductor light-emitting element, wherein in the fifth or sixth invention, the dielectric material as the protective layer comprises a material having a refractive index smaller than that of materials constituting the p-type layer, the active layer and the n-type layer.

An eighth invention is a group III nitride semiconductor light-emitting element, wherein in the first to fourth inventions, the protective layer is a high resistant ion-implanted region in a film form by implanting ions in the side surface and the bottom surface of the groove, and the p-electrode is formed on the side surface and the bottom surface of the groove through the protective layer.

A ninth invention is a group III nitride semiconductor light-emitting element, wherein in the first to eighth inventions, the insulating film is Al₂O₃, CeO₂, HfO₂, MgO, Nb₂O₅, Ta₂O₅, Y₂O₃ or ZrO₂.

According to the first invention, when the light-emitting element is encapsulated with an encapsulating resin, a first insulating film is located between the encapsulating resin and the fine irregularities, and the refractive index of the first insulating film is from 1.5 to 2.3 which is smaller than the refractive index of the group III nitride semiconductor and larger than the refractive index of the encapsulating resin. As a result, light is reflected at the interface between the fine irregularities and the encapsulating resin, thereby preventing light extraction efficiency from being deteriorated, and the light extraction efficiency can be improved. Furthermore, light confined in an element surface direction can be reflected to the n-type layer side by the grooves, and can efficiently be emitted outside by the fine irregularities. As a result, the light extraction efficiency can be improved.

The groove can be a plurality of dot-like patterns as in the second invention, and when the dot-like groove has a pattern arranged in a matrix shape as in the third invention, the light extraction efficiency can be improved without impairing uniformity of light emission.

The groove can be a lattice-like pattern as in the fourth invention, and similar to the third invention, the light extraction efficiency can be improved without impairing uniformity of light emission.

The groove may be filled with a dielectric material which is the protective layer as in the fifth invention. When the protective layer is a film-like dielectric material and the groove is filled with the p-electrode through the protective layer as in the sixth invention, light can be reflected to the n-type layer side by the p-electrode. As a result, the light extraction efficiency can further be improved. When the material of the protective layer is a material having a refractive index smaller than that of materials constituting the p-type layer, the active layer and the n-type layer as in the seventh invention, reflectance of light by the groove can further be enhanced, and the light extraction efficiency can further be improved.

According to the eighth invention, the light extraction efficiency can be improved similar to the sixth invention, and additionally because the ion-implanted region is used as the protective layer, adhesiveness of the p-electrode is superior to the case of using a dielectric material as the protective layer, and reliability of an element can be improved.

The material of the insulating film can use Al₂O₃, CeO₂, HfO₂, MgO, Nb₂O₅, Ta₂O₅, Y₂O₃ or ZrO₂ as in the ninth invention.

### BRIEF DESCRIPTION OF THE DRAWINGS

FIG. 1 is a cross-sectional view showing a constitution of a light-emitting element 100 of Example 1.

FIG. 2 is a plane view showing the constitution of the light-emitting element 100 of Example 1.

FIG. 3A is a view showing a production step of the light-emitting element 100 of Example 1.

FIG. 3B is a view showing the production step of the light-emitting element 100 of Example 1.

FIG. 3C is a view showing the production step of the light-emitting element 100 of Example 1.

FIG. 3D is a view showing the production step of the light-emitting element 100 of Example 1.

FIG. 3E is a view showing the production step of the light-emitting element 100 of Example 1.

FIG. 3F is a view showing the production step of the light-emitting element 100 of Example 1.

FIG. 3G is a view showing the production step of the light-emitting element 100 of Example 1.

FIG. 3H is a view showing the production step of the light-emitting element 100 of Example 1.

FIG. 4 is a cross-sectional view showing a constitution of a light-emitting element 200 of Example 2.

FIG. 5 is a plane view showing a constitution of other light-emitting element of the present invention.

FIG. 6 is a cross-sectional view showing a constitution of a light-emitting element 300 of Example 3.

### DESCRIPTION OF THE PREFERRED EMBODIMENTS

Specific embodiments of the present invention are described below by reference to the examples, but the invention is not construed as being limited to the examples.

### Example 1

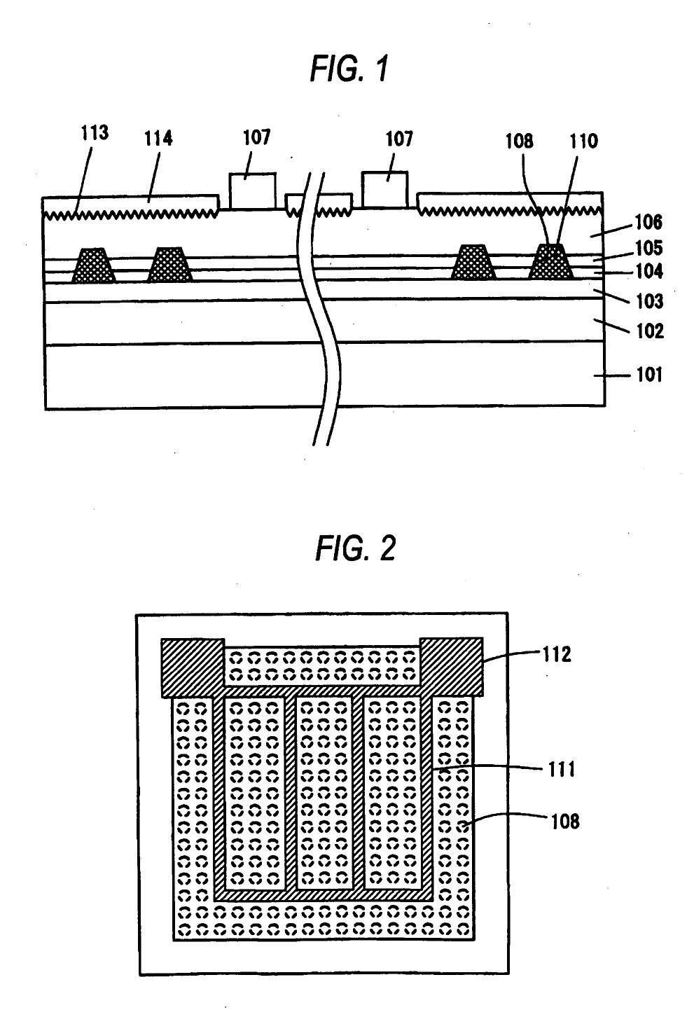

FIG. 1 is a cross-sectional view showing a constitution of a light-emitting element 100 of Example 1. The light-emitting element 100 comprises a support 101; a p-electrode 103 joined onto the support 100 through a low melting point metal layer 102; a p-type layer 104 comprising a group III nitride semiconductor, an active layer 105 and an n-type layer 106, laminated on the p-electrode 103 in this order; and an n-electrode 107 formed on the n-type layer 106.

The support 101 can use a conductive substrate comprising Si, GaAs, Cu, Cu—W or the like. The low melting point metal layer 102 can use a metal eutectic layer such as Au—Sn layer, Au—Si layer, Ag—Sn—Cu layer, Sn—Bi layer and the like, and can further use Au layer, Sn layer, Cu layer and the like, although not a low melting point metal layer. The support 101 and the p-electrode 103 may not be joined using the low melting point metal layer 102, but a metal layer such as Cu may directly be formed on the p-electrode 103 by plating, sputtering or the like, thereby forming the support 101. The p-electrode 103 is a low contact-resistant metal having high light reflectance, such as Ag, Rh, Pt, Ru or an alloy comprising those metals. Additionally, Ni, Ni alloy, Au alloy and the like can be used as a material of the p-electrode 103, and the p-electrode 103 may be a composite layer comprising a transparent electrode film such as ITO, and a high reflection metal film.

The p-type layer 104, the active layer 105 and the n-type layer 106 may have an optional constitution conventionally known as the constitution of the light-emitting element. The p-type layer 104 has, for example, a structure that an Mg-doped p-contact layer comprising GaN, and an Mg-doped p-clad layer comprising AlGaN are laminated in the order from the support 101 side. The active layer 105 has, for example, an MQW structure that a barrier layer comprising GaN and a well layer comprising InGaN are repeatedly laminated. The n-type layer 106 has, for example, a structure that an n-clad layer comprising GaN, and an n-type contact layer comprising GaN, doped with Si in high concentration are laminated in the order from the active layer 105 side.

A plurality of dot-like grooves 108 are formed on the surface at the side joining to the p-electrode 103 of the p-type layer 104. The groove 108 has a depth penetrating the p-type layer 104 and the active layer 105 and reaching the n-type layer 106. The shape of the groove 108 is a circular truncated cone such that a cross-section in an element surface direction is decreased toward the n-type layer 106 from the p-type layer 104.

The inside of the groove 108 is filled with a protective layer 110 comprising a dielectric material having translucency and insulating properties in order to prevent leakage and short circuit of current. The material of the protective layer 110 is a material having a refractive index smaller than the smallest refractive index of the materials constituting the p-type layer 104, the active layer 105 and the n-type layer 106. The material is, for example, SiO₂. The refractive index of the protective layer 110 is desirably 2.0 or less, and more desirably 1.6 or less. Critical angle of light entering the protective layer 110 from the p-type layer 104, the active layer 105 and the n-type layer 106 can be decreased as the refractive index of the protective layer 110 is decreased. Therefore, the amount of light totally reflected to the n-type layer side is increased, and the light extraction efficiency can further be improved.

The slant angle of the side surface of the groove 108 is desirably from 30 to 85°, and more desirably from 40 to 80°, to the element surface. The reason for this is that the light angle can further improve the light extraction efficiency. The shape of the groove 108 is not limited to the circular truncated cone, but may be circular cone, pyramid, truncated pyramid and the like, and may further be an infinite form.

FIG. 2 is a plane view seeing the light-emitting element 100 from the n-electrode 107 side. The n-electrode 107 comprises a wiring part 111 and two pad parts 112, as shown in FIG. 2. The two pad parts 112 are arranged in two corners at the side of a certain one side of the square light-emitting element 100, respectively. The wiring part 111 is formed in a pattern that rectangles, the sides of which being aligned in parallel to the sides of a square which is plane shape of the light-emitting element 100, are arranged in its shorter direction, and is connected the two pad parts 112. The n-type electrode 107 uses, for example, Cr/Ti/Ni/Au.

The grooves 108 are arranged in a matrix shape as shown in FIG. 2. The region having the grooves 108 provided thereon is that the thickness of the n-type layer 106 is small, thereby increasing sheet resistance. Because the grooves 108 are arranged in a periodically matrix shape with equal distance, the region having high sheet resistance of the n-type layer 106 is periodically present in a dot shape with equal distance, and because the region that is partitioned by the high sheet resistance region of the n-type layer 106 is not present, current diffusivity in the element surface direction is not greatly impaired. Furthermore, when the wiring part 111 is equally formed such that the same number of the dot-like grooves 108 is included in each rectangular pattern by the wiring part 111, current diffusivity in the element surface direction is prevented from being deteriorated.

The arrangement of the grooves 108 is not always required to be such a matrix shape. However, the grooves 108 are desirably arranged periodically with equal distance in order to diffuse current in the element surface direction, thereby making light emission uniform. The grooves 108 may be formed at positions facing the wiring part 111 and the pad part 112 of the n-electrode 107 in a vertical direction to the element surface direction, and may be formed at a position that does not face those.

The fine irregularities 113 are formed on the surface at the side joining to the n-electrode 107 of the n-type layer 106, except for the region having the n-electrode 107 formed thereon. The fine irregularities 113 are that a number of fine six-sided pyramids are formed, and an angle between the side surface of the six-sided pyramid and the element surface is about 60°. The fine irregularities 113 improve the light extraction efficiency. The n-electrode 107 formation region on the surface at the side of the n-type layer 106 to which the n-electrode is joined does not have the fine irregularities 113, and remains flat. The reason for this is to prevent that light is multiply-reflected between the n-type layer and the irregularities 113 and decays, and the light extraction efficiency is deteriorated.

An insulating film 114 comprising ZrO₂ is formed on the fine irregularities 113. Other than ZrO₂, materials having translucency and insulating properties and having a refractive index of from 1.5 to 2.3 may be used. For example, materials such as Al₂O₃, CeO₂, HfO₂, MgO, Nb₂O₅, Ta₂O₅ and Y₂O₃ can be used as the insulating film 114. The materials of the protective layer 110 and the insulating film 114 may be the same. More desired refractive index of the insulating film 114 is from 1.7 to 2.1. The insulating film 114 may be formed on not only the irregularities 113, but may be formed so as to cover the side surfaces of the n-type layer 106, the active layer 105 and the p-type layer that are exposed on the edge of the light-emitting element 100. This constitution can prevent leakage and short circuit of current at the side edge of the light-emitting element 100.

According to the constitution of the light-emitting element 100, light confined in a horizontal direction in the vicinity of the active layer 105 can be reflected to the n-type layer 106 side by the side surface of the groove 108, and the light extraction efficiency can be improved. Furthermore, when the light-emitting element 100 is encapsulated with a resin such as silicone, the insulating film 114 is located between the resin layer and the fine irregularities 113, and the refractive index of the insulating film 114 is smaller than the refractive index (about 2.4) of the group III nitride semiconductor, and is larger than the refractive index (about 1.45) of the silicone resin. As a result, light extraction is not inhibited by reflection between the fine irregularities 114 and the resin layer, and the light extraction efficiency can be improved.

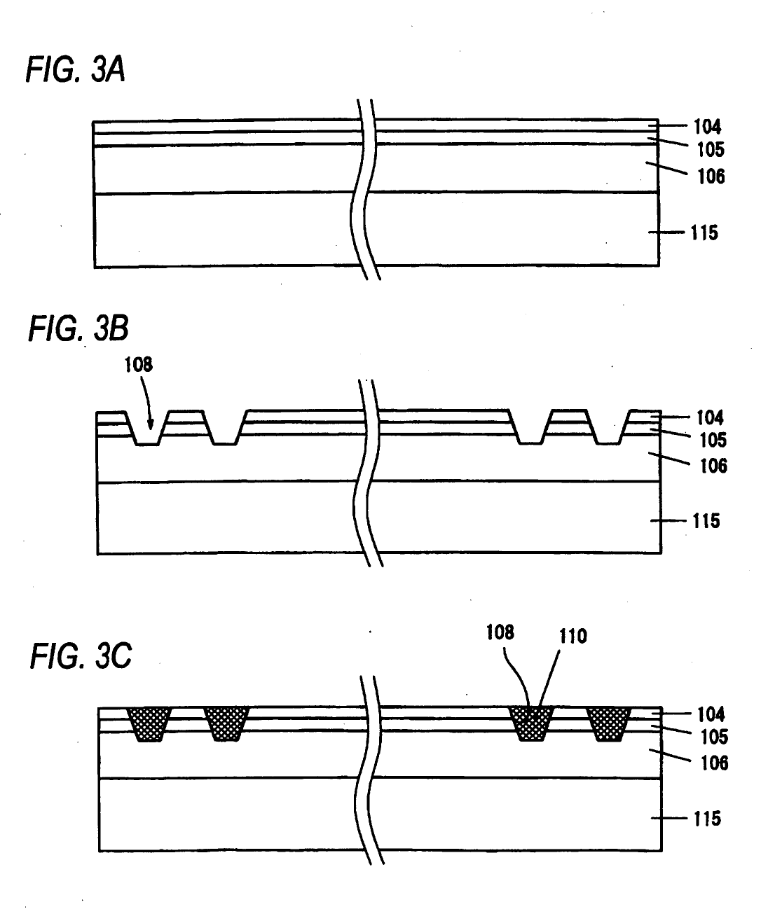

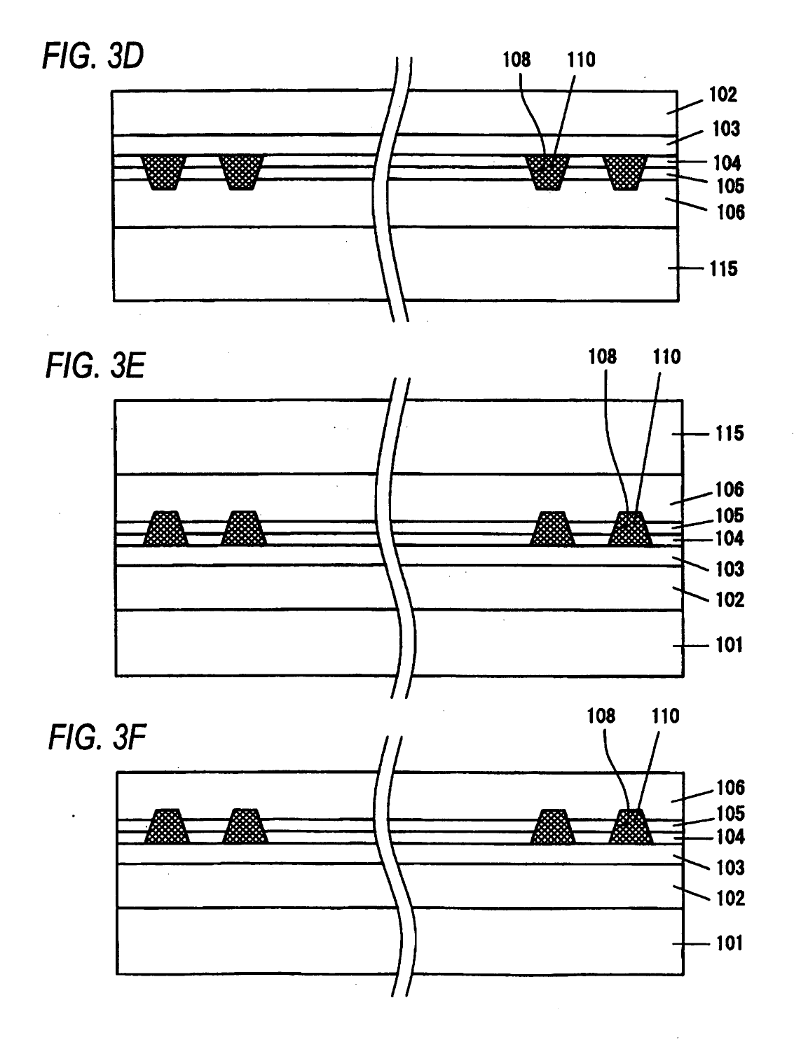

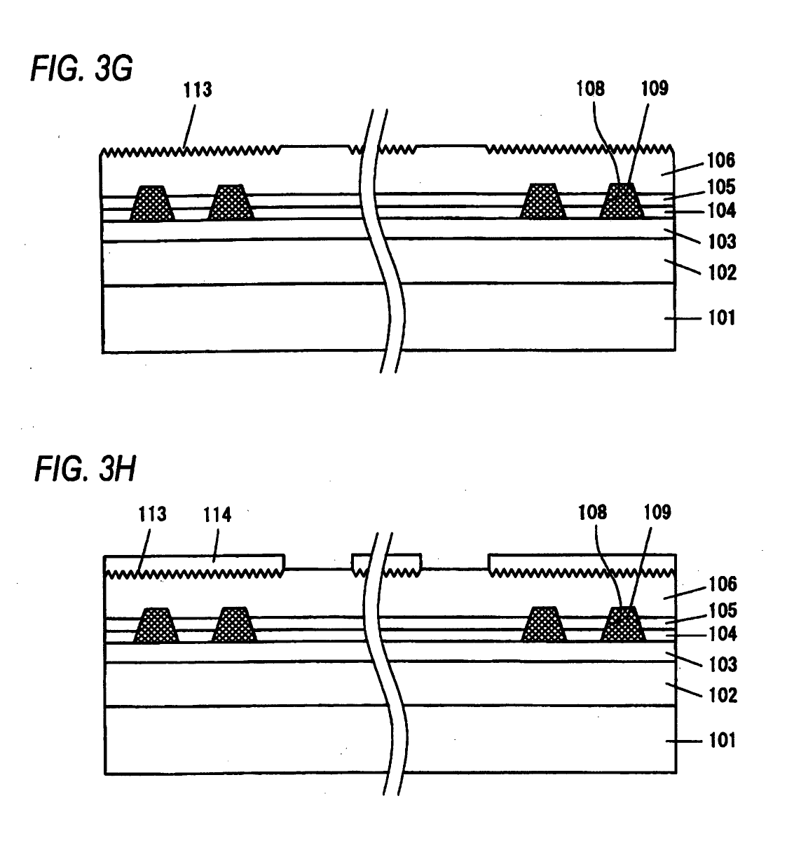

The production step of the light-emitting element 100 is described below by reference to FIG. 3.

The n-type layer 106 comprising the group III nitride semiconductor, the active layer 105 and the p-type layer 104 are laminated in this order on a sapphire substrate 115 by MOCVD method (FIG. 3A). Raw material gases used in the MOCVD method are that ammonia (NH₃) is used as a nitrogen source, trimethyl gallium (Ga(CH₃)₃) is used as a Ga source, trimethyl indium (In(CH₃)₃) is used as an In source, trimethyl aluminum (Al(CH₃)₃) is used as an Al source, silane (SiH₄) is used as an n-type doping gas, cyclopentadienyl magnesium (Mg(C₅H₅)₂) is used as a p-type doping gas, and H₂ or N₂ is used as a carrier gas. Other than the sapphire substrate 115, SiC, ZnO, spinel and the like can be used.

A mask comprising SiO₂, having a pattern that a window is opened on a region forming the groove 108 is formed on the p-type layer 104, and dry etching using chlorine-type gas plasma is conducted. A plurality of grooves 108 having a depth reaching the n-type layer 106, arranged in a matrix shape are formed by the treatment. Thereafter, the mask is removed by buffered hydrofluoric acid or the like (FIG. 3B).

A translucent insulating layer is formed on the p-type layer 103 so as to fill in the groove 108. Thereafter, etch back is conducted until the p-type layer 103 is exposed, thereby the protective layer 110 filling the inside of the groove 108 is formed (FIG. 3C).

The p-electrode 103 is formed on the p-type layer 104 and the protective layer 110 by a vacuum deposition method, and a low melting point metal layer 102 is formed thereon (FIG. 3D).

A support 101 is provided, and the support 101 and the p-electrode 103 are joined through the low melting point metal layer 102 (FIG. 3E). It is better that a diffusion preventive layer not shown is previously formed between the p-electrode 103 and the low melting point metal layer 102, thereby preventing a metal of the low melting point metal layer 102 from being diffused to the p-electrode 103 side.

Laser light is emitted from the sapphire substrate 115 side, thereby separating and removing the sapphire substrate 115 (FIG. 3F).

A mask comprising SiO₂ is formed on the n-type layer 106 surface exposed by removal of the sapphire substrate 114, which ultimately becomes a region forming the n-electrode 107, and a wafer is dipped in a TMAH (tetramethylammonium hydroxide) aqueous solution having a concentration of 2.2%, thereby forming the fine irregularities 113 on a region of the n-type layer 106 surface which is not covered with the mask. Thereafter, the mask is removed by buffered hydrofluoric acid (FIG. 3G). The formation of the fine irregularities can use an aqueous solution of KOH, NaOH or the like, other than TMAH.

An insulating film is formed over the entire surface of the n-type layer 106 by CVD method, and the insulating film on a region of the flat n-type layer 106 on which the fine irregularities 113 are not formed is removed by dry etching, thereby forming the insulating film 114 on the fine irregularities 113 (FIG. 3H). It is better that mesa groove formation of element separation is conducted before this step, and the insulting layer 114 is formed on the side surface of the mesa groove.

The n-electrode 107 having a wiring part 111 and two pad parts 112 are formed on the flat n-type layer 106 on which the fine irregularities 113 are not formed, by a lift-off process using a resist. The support 101 is polished to reduce its thickness, a back electrode (not shown) is formed on the surface opposite the low melting point metal layer 102 side of the support 101, and chip separation is conducted by laser dicing. Thus, the light-emitting element 100 as shown in FIG. 1 is produced.

### Example 2

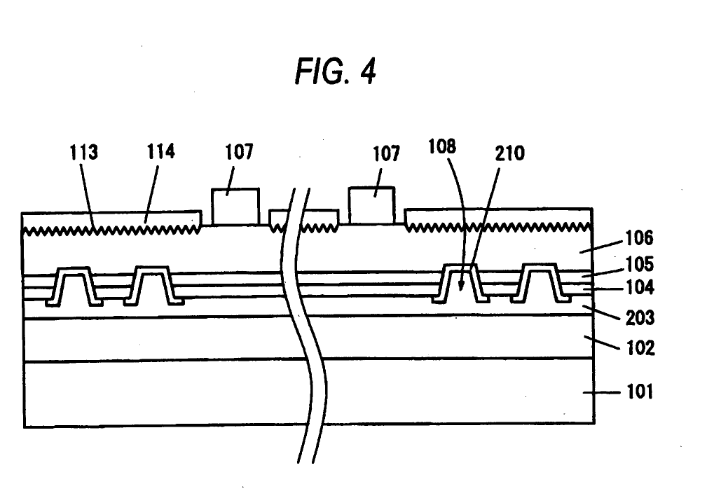

FIG. 4 is a cross-sectional view showing a constitution of a light-emitting element 200 of Example 2. The light-emitting element 200 of Example 2 has the same constitution as the light-emitting element 100, except that a protective layer 210 is used in place of the protective layer 110 of the light-emitting element 100, and a p-electrode 203 is used in place of the p-electrode 103.

The protective layer 210 is a dielectric material formed in a film shape along the shape of the bottom surface and the side surface of the grove 108, and is provided to prevent leakage and short circuit of current as same as in the protective layer 110. The protective layer 210 comprises the same material as in the protective layer 110. That is, the material of the protective layer 210 is a material having translucency and insulating properties, and is a material having a refractive index smaller than the smallest refractive index of the materials constituting the p-type layer 104, the active layer 105 and the n-type layer 106. The protective layer 210 may be a multilayered film, and may have a structure having high reflectance utilizing Bragg reflection.

The p-electrode 203 is formed on the surface at the support 101 side of the p-type layer 104, and is formed so as to fill in the groove 108 through the protective layer 210. The p-electrode 203 comprises a low contact-resistant metal having high light reflectance, such as Ag, Rh, Pt, Ru or alloys comprising those metals as a main component, similar to the p-electrode 103.

A metal film having high reflectance comprising a material different from the material of the p-electrode 203 may further be provided between the protective layer 210 and the p-electrode 203. Furthermore, the groove 108 is not filled with the p-electrode 203, but may be filled with a metal layer having high reflectance comprising a material different from the material of the p-electrode 203 through the protective layer 210.

According to the constitution of the light-emitting element 200, light confined in a horizontal direction in the vicinity of the active layer 105 can efficiently be reflected to the n-type layer 106 side by the side surface of the groove 108 (interface between the protective layer 210, and the n-type layer 106, the active layer 105 and the p-type layer 104), and light passing through the protective layer 210 can be reflected to a direction toward an output direction of the n-type layer 106 by the p-electrode 203 or the metal layer having high reflectance. As a result, the light extraction efficiency can be improved, and light output can be improved.

### Example 3

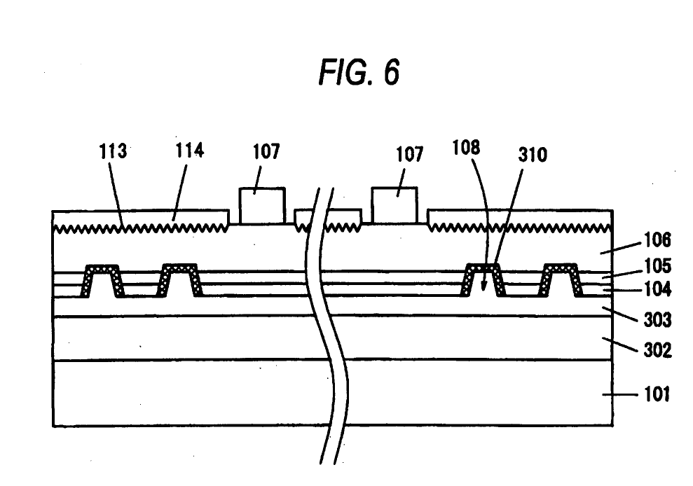

FIG. 6 is a cross-sectional view showing a constitution of a light-emitting element 300 of Example 3. The light-emitting element 300 of Example 3 has the constitution in which a protective layer 310 and a p-electrode 303, described hereinafter are used in place of the protective layer 210 and the p-electrode 203 of the light-emitting element 200, and other constitutions are the same as in the light-emitting element 200.

The protective layer 310 is a film-like, high resistant ion-implanted region formed by implanting ions in the bottom surface and the side surface of the groove 108. That is, the ion-implanted region is a high resistant group III nitride semiconductor in which a crystal structure has been destroyed by implantation of ions. The protective layer 310 which is the ion-implanted region is to prevent leakage and short circuit of current, similar to the protective layers 110 and 210 comprising a dielectric material. Furthermore, the protective layer 310 is one that a crystal structure of the group III nitride semiconductor has been destroyed, and therefore has translucency. Thickness and resistance value of the protective layer 310 can be controlled by the kind of an element to be implanted, the amount of an ion implanted, and an accelerating voltage. The element to be implanted is Ar, N and the like.

The p-electrode 303 is formed on the surface at the support 101 side of the p-type layer 104, and is formed so as to fill in the groove 108 through the protective layer 310. The p-electrode 303 may be formed in film shape along the side surface and the bottom surface of the groove 108 through the protective layer 310. The p-electrode 303 comprises a low contact-resistant metal having high light reflectance such as Ag, Rh, Pt, Ru and alloys comprising those metals as a main component, similar to the p-electrode 103. The p-electrode 303 contacts the protective layer 310. Because the protective layer 310 is the high resistant ion-implanted region in which a crystal structure of the group III nitride semiconductor has been destroyed, the protective layer 310 has excellent adhesiveness as compared with the case that the protective layer 310 is a dielectric material, and reliability of the light-emitting element 300 can be improved.

According to the light-emitting element 300 as described above, the light extraction efficiency can be improved and light output can be improved, similar to the light-emitting element 200 of Example 2.

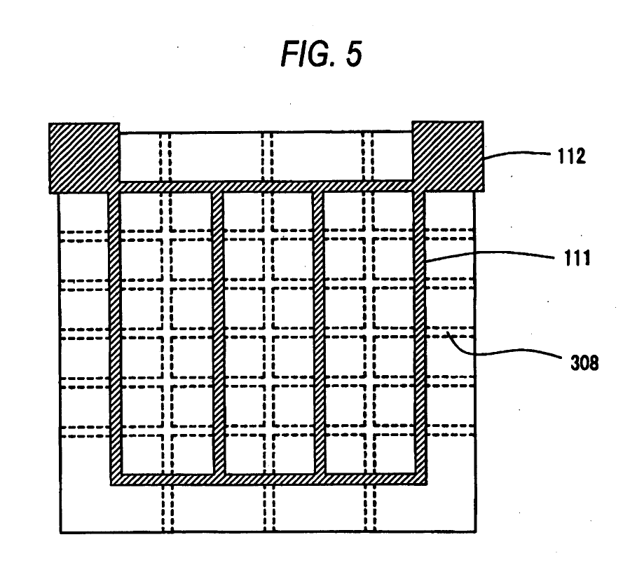

In Examples 1 to 3, a plurality of dot-like grooves was provided in a dot shape. However, it is not always necessary to be dot-like grooves, and grooves having line-like pattern such as a straight line shape, a curve shape and a combination thereof may be provided. For example, FIG. 5 is an embodiment in which lattice-like grooves 308 comprising crossed lines having a given width are provided. In this case, the region having the groove 308 provided thereon is that the thickness of the n-type layer 106 is decreased and sheet resistance is increased. As a result, current diffusion to a rectangular regions partitioned by the grooves 308 is impaired. However, the wiring part 111 of the n-electrode 107 is formed so as to pass through all of rectangular regions partitioned by the grooves 308, and this embodiment prevents current diffusivity in the element surface direction from being deteriorated. In the case of forming the groove in a line shape, line width on the surface of the p-type layer is desirably from 0.5 to 30 μm, and more preferably from 1 to 15 μm. The line width on the bottom surface of the groove is desirably from 0 to 25 μm, and more desirably from 0 to 12 μm. The embodiment that the line width on the bottom surface of the groove is 0 is the case that the cross-section shape of the groove is a triangle.

In Examples 1 to 3, a laser lift-off process is used for removal of the sapphire substrate. However, a chemical lift-off process may be used that a buffer layer capable dissolving in chemicals is formed between the sapphire substrate and the n-type layer, and after joining to the support, the buffer layer is dissolved by the chemicals to separate and remove the sapphire substrate.

The group III nitride semiconductor light-emitting element of the present invention can be used in display devices, lighting systems and the like.

What is claimed is:

1. A group III nitride semiconductor light-emitting element, comprising:
a conductive support;
a p-electrode located on the support;
a p-type layer comprising a group III nitride semiconductor, an active layer and an n-type layer, that are located on the p-electrode in this order;
an n-electrode located on the n-type layer, the n-type layer having fine irregularities provided at a surface of the n-type layer that is located at the n-electrode side;
a translucent insulating film having a refractive index of from 1.5 to 2.3, formed so as to cover the fine irregularities;
a groove having a depth reaching at least the n-type layer from a surface of the p-type layer that is located at the p-electrode side; and
a translucent insulating protective layer formed on a side surface and a bottom surface of the groove;
wherein the side surface of the groove has a slant such that a cross-section in an element surface direction of the groove is decreased toward the n-type layer side.

2. The group III nitride semiconductor light-emitting element as claimed in claim 1, wherein the groove has a dot shape, and a plurality of the grooves are formed.

3. The group III nitride semiconductor light-emitting element as claimed in claim 2, wherein the grooves are arranged in a matrix shape.

4. The group III nitride semiconductor light-emitting element as claimed in claim 1, wherein the groove is formed in a lattice shape.

5. The group III nitride semiconductor light-emitting element as claimed in claim 1, wherein the protective layer is a dielectric material formed so as to fill in the groove.

6. The group III nitride semiconductor light-emitting element as claimed in claim 1, wherein the protective layer is a dielectric material formed in a film form, and the groove is filled with the p-electrode through the protective layer.

7. The group III nitride semiconductor light-emitting element as claimed in claim 5, wherein the dielectric material as the protective layer comprises a material having a refractive index smaller than that of materials constituting the p-type layer, the active layer and the n-type layer.

8. The group III nitride semiconductor light-emitting element as claimed in claim 6, wherein the dielectric material as the protective layer comprises a material having a refractive index smaller than that of materials constituting the p-type layer, the active layer and the n-type layer.

9. The group III nitride semiconductor light-emitting element as claimed in claim 1, wherein the protective layer is a high resistant ion-implanted region in a film form formed by implanting ions in the side surface and the bottom surface of the groove, and the p-electrode is formed on the side surface and the bottom surface of the groove through the protective layer.

10. The group III nitride semiconductor light-emitting element as claimed in claim 1, wherein the insulating film is Al₂O₃, CeO₂, HfO₂, MgO, Nb₂O₅, Ta₂O₅, Y₂O₃ or ZrO₂.
